(19) United States
(12) Patent Application Publication
(10) Pub. No.: US 2025/0274211 A1
(43) Pub. Date: Aug. 28, 2025

(54) SYSTEM AND METHOD OF CALIBRATING A CLOCK DEVICE

(71) Applicant: ADTRAN Networks SE, Meiningen (DE)

(72) Inventor: Avi HAYUN, Kfar-Saba (IL)

(21) Appl. No.: 18/973,344

(22) Filed: Dec. 9, 2024

(30) Foreign Application Priority Data
Feb. 26, 2024 (EP) 24159620.4

(51) Int. Cl. H04J 3/06; H04L 43/0864

(52) U.S. Cl. CPC H04J 3/0658; H04L 43/0864

(57) ABSTRACT

Some embodiments are directed toward a technique for calibrating a clock device operatively connected to an antenna and receiving precision time therefrom via a cable. The technique enables increasing accuracy of the clock device by embedded time calibration with the help of continuously sampling antenna cable delays and enabling respective time corrections. The method includes: a) disabling, by the clock device, antenna's powering thus giving rise to an unpowered antenna; b) generating by a measurement module a pulse and forwarding it toward the unpowered antenna, wherein the measurement module is implemented within the clock device; c) measuring, by the measurement module, the roundtrip delay between the generated pulse and a measured signal reflected by the unpowered antenna, thereby obtaining a cable delay; and d) providing time calibration in the clock device in accordance with the cable delay. Continuously repeating operations a)-d) can enable embedded compensation for varying cable delay.

### CROSS-REFERENCES TO RELATED APPLICATIONS

The present application claims benefit from EP patent application Ser. No. 24/159,620.4 filed on Feb. 26, 2024 and incorporated hereby by reference in its entirety.

### TECHNICAL FIELD

The presently disclosed subject matter relates to the field of data communication, and, more particularly, to time calibration of clock devices in data networks.

### BACKGROUND

Proper operation of a data network (e.g. a telecommunication network, a distributed computer system, etc.) requires phase and/or frequency synchronization between various entities therein. Synchronization can be achieved, for example, by exchanging timing information (time-transfer) across the network in accordance with time-transfer (TT) protocols (e.g. IEEE 1588 Precision Time Protocol (PTP), Network Time Protocol (NTP), etc.

FIG. 1 schematically illustrates a non-limiting example of time distribution network 100, including a plurality of clock nodes (referred to hereinafter also as clock devices) denoted as 11-1-11-5 and implementing a time-transfer protocol as known in prior art. The exemplary time distribution network 100 can operate on top of a packet-compatible communication network (not shown) which comprises a plurality of network nodes organized in ring, bus, tree, star, or mesh topologies, or a combination of different topologies. Clock nodes correspond to hosting network nodes of the underlying data network and can constitute parts of the respective network nodes.

Each clock node comprises a processing and memory circuitry (PMC) and a clock circuitry.

Clock nodes 11-2-11-4 are operatively connected to the clock node 11-1 via respective clock ports (not shown). Clock node 11-1 is configured to be the source of synchronization data in the network, i.e. to serve as a primary reference clock (PRC) node providing the timing reference to the clock nodes 11-2-11-4.

Clock node 11-1 (referred to hereinafter as PRC device) receives Coordinated Universal Time (UTC)-based time information from an external time reference, most commonly a GNSS (Global Navigation Satellite System) source. Clock node 11-4 is configured as a boundary clock node and is configured to provide reference time information to node 11-5.

For purpose of illustration only, the following description is provided for a GNSS source of the external time reference and GNSS receiver, accordingly. Those skilled in the art will readily appreciate that the teachings of the presently disclosed subject matter are, likewise, applicable to any other suitable satellite constellation including STL (Satellite Time and Location).

Further to clock circuitry 12 and PMC 13, PRC device 11-1 comprises GNSS receiver 14 connected to an antenna device 15 with the help of cable 16 (referred to hereinafter also as “antenna cable”). It is noted that antenna cable 16 can be any cable suitable for connection between antenna 15 and GNSS receiver 14 (e.g. coaxial cable, fiber, etc.). It is further noted that antenna device 15 (referred to hereinafter as “antenna”) comprises one or more electronic components (e.g. an amplifier and/or other signal processing elements) and need to be powered for its operation. In certain embodiments, PRC device 11-1 can operate as a power source for antenna 15.

By way of non-limiting example, GNSS receiver 14 can be a GNSS disciplined oscillator that constantly receives signals from satellites via antenna 15 and adjusts its clock to maintain precise time synchronization.

Clock circuitry 12 takes the precise time information received from the GNSS receiver 14 and generates highly accurate time signals. These signals are then distributed across the time distribution network 100 to synchronize various devices and systems to the same precise time.

GNSS UTC time is determined when a signal is received at antenna 15. Accordingly, cable 16 between antenna 15 and GNSS receiver 14 causes signal propagation delays (referred to hereinafter also as “cable delays”), thus reducing accuracy of time calculation at GNSS receiver 14.

The contemporary art assumes that the expected delays in antenna cable (referred to hereinafter also as “cable delays”) can be calculated in accordance with the cable length and specification or can be measured by an external test device and, accordingly, PRC devices can be calibrated prior to operational process.

### GENERAL DESCRIPTION

For purpose of illustration only, the following description is provided for a PRC device. Those skilled in the art will readily appreciate that the teachings of the presently disclosed subject matter are, likewise, applicable to any other clock device receiving precise time via cable.

The inventor has recognized that obtaining cable length/specification data before or during installation can present a formidable task. Furthermore, antenna cable length and characteristics may vary during the operational process of PRC device, for example due to temperature variations and/or aging of the cable. Therefore, the respective cable delays are not constant, and the preliminary calibration is not stable and not always available.

Accordingly, the inventor has appreciated that there is a need to provide embedded continuous calibration of a PRC device to compensate for the varying antenna cable delays with minimized disruption to the normal operational process of the device. Further, there is a need to eliminate the necessity of knowing cable length and specifications during the device installation.

In accordance with the presently disclosed subject matter, there is provided a technique of increasing the accuracy of a clock device by in-band calibrating thereof with the help of continuously sampling antenna cable delays.

In accordance with certain aspects of the presently disclosed subject matter, there is provided a method of time calibration of a clock device receiving precision time information from an antenna via a cable, the clock device being operatively connected to the antenna and powering thereof. The method comprises: disabling, by the clock device during operational process thereof, antenna's powering thus giving rise to an unpowered antenna; generating by a measurement module a pulse and forwarding it toward the unpowered antenna, wherein the measurement module is implemented within the clock device; measuring, by the measurement module, the roundtrip delay between the generated pulse and a measured signal reflected by the unpowered antenna, thereby obtaining a cable delay; and providing time calibration in the clock device in accordance with the cable delay.

In accordance with further aspects of the presently disclosed subject matter, the method can further comprise switching withing the clock device between an operation mode and a calibration mode comprising operations a)-d), wherein switching from the operation mode to the calibration mode is provided prior to generating the pulse towards the unpowered antenna and enables signals incoming from the antenna to be routed to the measurement module, and wherein switching back to the operation mode comprises enabling antenna powering.

Switching between the operation and calibration modes can be continuously repeated, thereby enabling embedded compensation for varying cable delay.

In accordance with further aspects of the presently disclosed subject matter, measuring the roundtrip delay between the generated pulse and the measured signal reflected by the unpowered antenna can comprise setting a threshold value defining when a reflected signal is recognized as the measured signal reflected by antenna, wherein a reflected signal is recognized as the measured signal when the absolute value of an amplitude thereof exceeds the threshold value.

The measurement module can change the threshold value and provide sampling reflected signals at a sampling point corresponding to the changed threshold value.

The method can further comprise multiple sampling at each of several sampling points and determining the optimal sampling point enabling the minimal deviation of sampling results repeated at a specific point, wherein the measured signal reflected by antenna is sampled at the optimal sampling point.

In accordance with further aspects of the presently disclosed subject matter, the method can further comprise: prior to connecting the cable to the antenna, generating by the measurement module a pulse toward the cable; measuring, by the measurement module, the roundtrip delay between the generated pulse and an open-end reflected signal, thereby obtaining an open-end cable delay; and using the open-end cable delay as a baseline when obtaining the cable delay and/or for calculating a length of the cable.

In accordance with other aspects of the presently disclosed subject matter, there is provided a clock device operatively connected to an antenna and configured to power thereof, the clock device further configured to receive precision time information from the antenna via a cable and comprises a measurement module operatively connected to a processing and memory circuitry (PMC). The PMC is configured to enable un-powering the antenna thus giving rise to an unpowered antenna. The measurement module is configured to generate a pulse and forward it toward the unpowered antenna and measure the roundtrip delay between the generated pulse and a measured signal reflected by the unpowered antenna, thereby obtaining a cable delay. The PMC is further configured to calculate time correction in accordance with the cable delay and to enable respective time calibration in the clock device.

In accordance with further aspects of the presently disclosed subject matter, the clock device can further comprise a GNSS (Global Navigation Satellite System) receiver operatively connected to the PMC and a switch operatively connected to the GNSS receiver, to the PMC and to the measurement module. The PMC can be further configured to set the switch so to enable switching between an operation mode when signals incoming from the antenna are routed to the GNSS receiver and a calibration mode that comprises un-powering the antenna and measuring the cable delay.

The PMC can be further configured to enable antenna powering wherein switching back to the operation mode. The PMC can be further configured to set the calculated time correction to GNSS receiver. The PMC can be further configured to enable continuously repeating the switching between the operation and calibration modes, thereby enabling embedded compensation for varying cable delays.

Among advantages of certain embodiments of the presently disclosed subject matter are eliminating necessity in knowing cable specifications and length; embedded capability to compensate temperature and aging effects during PRC device operational process; capability to detect damages on the cable, etc.

### BRIEF DESCRIPTION OF THE DRAWINGS

To understand the invention and to see how it can be carried out in practice, embodiments will be described, by way of non-limiting examples, with reference to the accompanying drawings, in which:

FIG. 1 illustrates a generalized schematic architecture of an exemplary time distribution network as known in prior art;

FIG. 2a illustrates a generalized flow chart of time calibrating a PRC device in accordance with certain embodiments of the presently disclosed subject matter;

FIG. 2b illustrates reflection signal in open cable and in connected non-powered antenna;

FIG. 3a illustrates a generalized block diagram of a PRC device in accordance with certain embodiments of the presently disclosed subject matter;

FIG. 3b illustrates a schematic diagram of operating the PRC device in accordance with certain embodiments of the presently disclosed subject matter; and

FIG. 4 illustrates a generalized flow chart of operating a measurement unit in PRC device in accordance with certain embodiments of the presently disclosed subject matter.

### DETAILED DESCRIPTION

In the following detailed description, numerous specific details are set forth to provide a thorough understanding of the invention. However, it will be understood by those skilled in the art that the presently disclosed subject matter may be practiced without these specific details. In other instances, well-known methods, procedures, components and circuits have not been described in detail so as not to obscure the presently disclosed subject matter.

It is to be understood that the term “signal” used herein excludes transitory propagating signals but includes any other signal suitable to the presently disclosed subject matter.

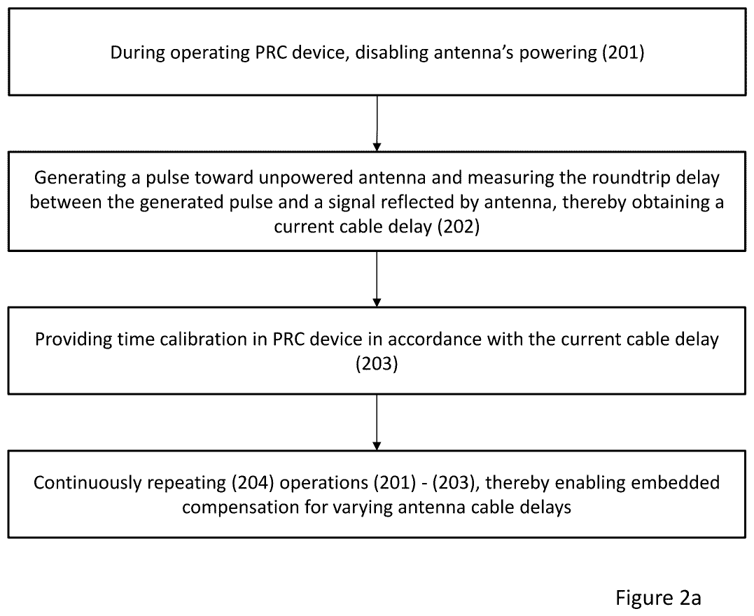

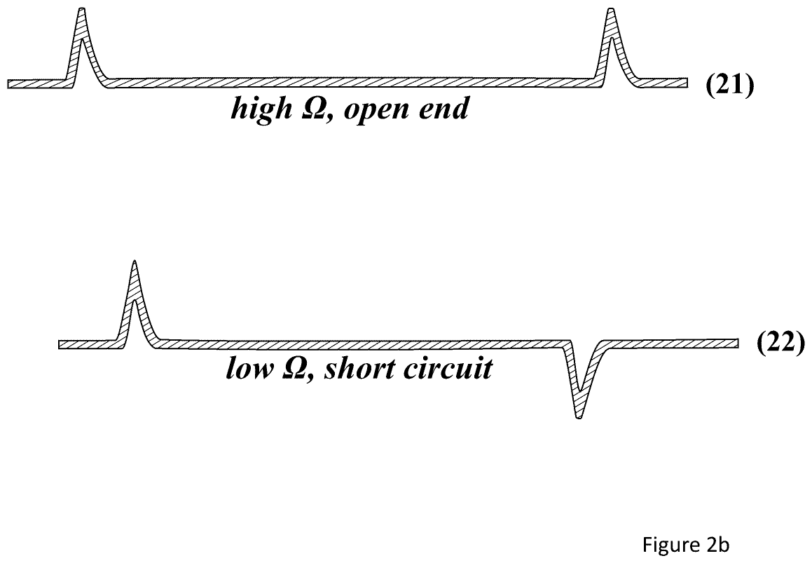

Bearing this in mind, attention is drawn to FIG. 2a illustrating a generalized flow chart of embedded calibrating a PRC device.

In accordance with certain embodiments of the presently disclosed subject matter, embedded time calibrating the PRC device is provided with the help of continuously sampling antenna cable delays.

Unless specifically stated otherwise, throughout the specification the term “embedded time calibration”, “embedded compensation”, “embedded measuring” and alike refer to the respective processes provided with the help of the measurement tools implemented within a device and during an operational process of the device, the operational process comprising an operation mode and a calibration mode.

Unless specifically stated otherwise, throughout the specification the terms “continuously calibrating”, “continuously sampling”, “continuously correcting” or alike refer to actions provided periodically and/or responsive to scheduled events and/or responsive to predefined events (e.g. predefined thresholds of changes of an external temperature, detected cable damages, etc.).

Sampling the antenna cable delays is provided with an unpowered antenna, i.e. antenna disconnected from an external power source (e.g. PRC device). As known, the reflection coefficient is the ratio of reflected wave to incident wave at point of reflection. This value varies from −1 (for short load) to +1 (for open load). Accordingly, as illustrated in FIG. 2b, the reflected signal is positive in the case (21) of open cable and negative in the case (22) for unpowered antenna which can be considered as a near “short load” case.

Thus, disabling antenna powering enables obtaining the reflected signal from the connected antenna.

Upon disabling (201) antenna's powering during the operational process of the clock device, the PRC device generates a pulse toward unpowered antenna and measures the roundtrip delay between the generated pulse and a signal reflected by antenna, thereby obtaining (202) a current cable delay. As the roundtrip delay includes both the forward and backward propagation, the current cable delay (i.e. one-way propagation delay between the PRC device and antenna) can be calculated as the total roundtrip delay divided by two.

Further, the PRC device calibrates (203) its clock in accordance with the measured current cable delay, i.e. generates the highly accurate time signals in accordance with precise time information corrected in accordance with the measured cable delay.

PRC device continuously repeats (204) operations (201)-(203), thereby enabling embedded compensation for varying antenna cable delays.

Optionally, PRC device can, in a similar manner, measure the roundtrip delay prior to operational process, when the cable is not yet connected to the antenna (open-end reflection). The resulting cable delay can be used to calculate the cable length and/or used as an accurate baseline for further delay measurements.

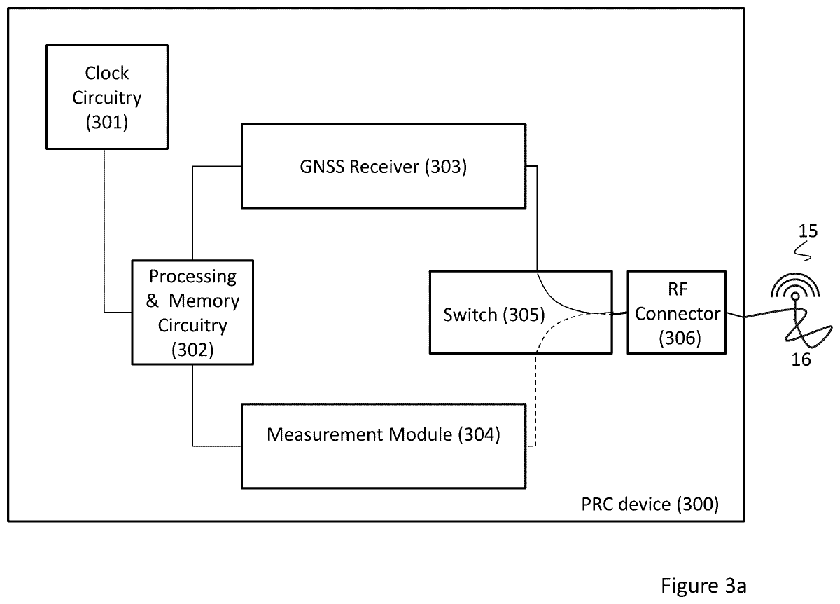

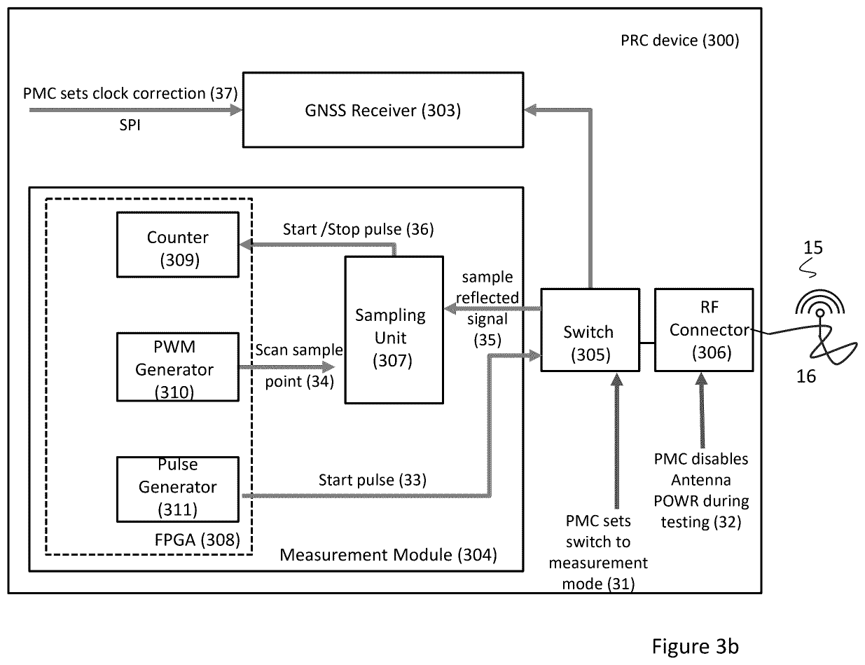

Referring to FIG. 3a, there is illustrated a generalized block diagram of a PRC device in accordance with certain embodiments of the presently disclosed subject matter.

PRC device 300 comprises a clock circuitry 301 operatively connected to a processing and memory circuitry (PMC) 302. PMC 302 is operatively connected to a GNSS receiver 303 and a measurement module 304. RF connector 306 is configured to enable connection of PRC device 300 to antenna cable 16. GNSS receiver 303 and measurement module 304 are operatively connected to switch 305 configured to provide them with switchable operative connection to RF connector 306.

FIG. 3b illustrates a schematic diagram that details the PRC device and operation thereof in accordance with certain embodiments of the presently disclosed subject matter.

Measurement module 304 comprises a sampling unit 307 operatively connected to switch 305, a counter 309 and a PWM (Pulse Width Modulation) generator 310. Measurement module 304 further comprises a pulse generator 311 operatively connected to counter 309 and to switch 305. PMC 302 (not shown in FIG. 3b for simplicity of illustration) is operatively connected to GNSS receiver 303, switch 305 and RF connector 306. Optionally, counter 309, PWM generator 310 and pulse generator 311 can be integrated into a Field Programmable Gate Array (FPGA) 308 operatively connected to PMC 302.

Switch 305 (e.g. an RF switch) is configured to switch between operation mode when signals incoming from antenna 15 are routed to GNSS receiver 303 and calibration mode enabling measuring the cable delays and respective calibration the clock device. PMC 302 continuously (i.e. periodically and/or responsive to scheduled events and/or responsive to predefined events) sets (31) switch 305 to the calibration mode. Concurrently, PMC 302 disables (32), at the beginning of calibration mode, antenna powering via RF connector 306 and enables antenna powering back when sampling is finished.

Responsive to a command received from PMC 302 upon disabling antenna powering, pulse generator 311 generates (33) a start pulse and sends it to switch 305. Switch 305 enables transferring the start pulse to counter 309.

Sampling unit 307 can be configured as a high-speed comparator capable of providing indication (stop pulse) when an absolute value of an amplitude of a reflected signal is higher than the threshold value of comparator's negative input point. Setting the threshold (and a respective sampling point) can be controlled by PWM generator 310. PWM generator 310 changes the threshold and enables scanning (34) of sampling points.

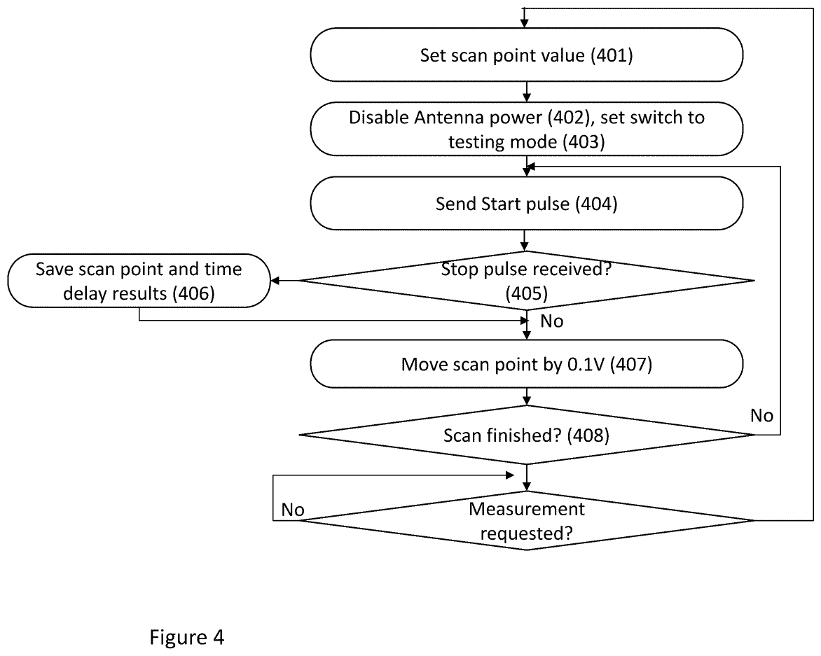

Sampling unit samples (35) reflected signal as further detailed with reference to FIG. 4 and provides (36) stop pulse to counter (309).

In certain embodiments, sampling is provided at the optimal sampling point enabling minimized threshold whilst the minimized deviation of sampling results repeated at the point. The optimal point can be determined by obtaining multiple samples at each of several sampling points and selecting the sampling point optimized by minimized deviations of sampling results and the threshold.

Counter (309) measures the roundtrip time between the start pulse and the stop pulse. Upon time-to-digital conversion, counter (309) sends the respective data to PMC 302 which calculates and accordingly sets (37) time corrections to GNSS receiver 303.

In certain embodiments PMC 302 can set the respective time corrections in GNSS receiver 303, while in other embodiments the time corrections can be provided directly in clock circuitry 301.

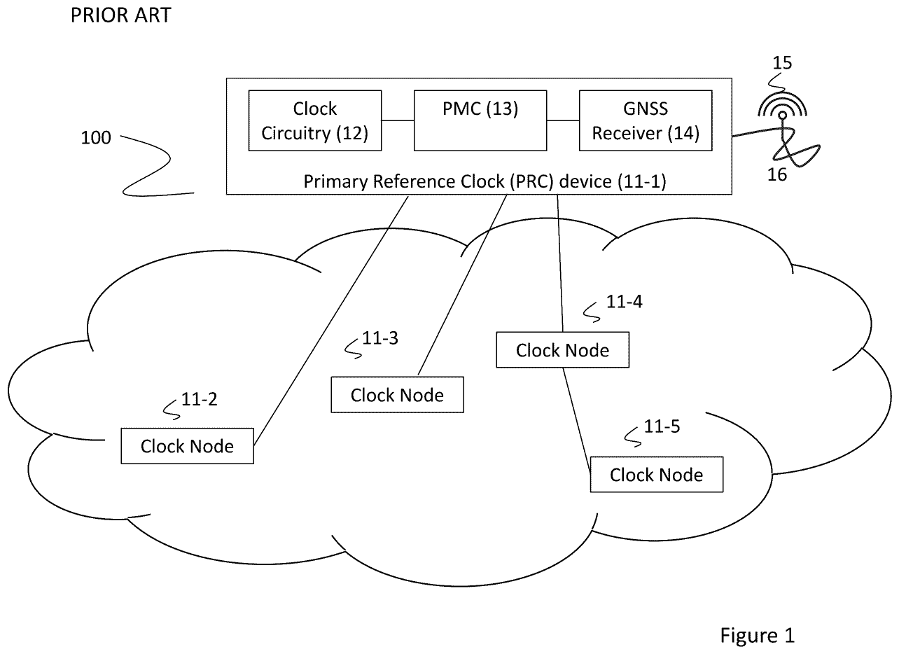

It is noted that the teachings of the presently disclosed subject matter are not bound by embodiments described with reference to FIG. 1, FIG. 3a and FIG. 3b. Equivalent and/or modified functionality can be consolidated or divided in another manner and can be implemented in any appropriate combination of software with firmware and/or hardware. Grandmaster/Boundary clock, GNSS receiver and measurement module can be integrated in a single enclosure or, alternatively, at least one of them can be implemented in a separate enclosure constituting a part of PRC device. The measurement module can be implemented as a separate module or as a part of Grandmaster/Boundary clock or GNSS receiver.

Likewise, a measurement module configured in accordance with the teachings of the presently disclosed subject matter can be integrated with clock circuitry of non-PRC device receiving precise time information via cable.

Referring to FIG. 4, a generalized flow chart of operating a measurement unit in PRC device in accordance with certain embodiments of the presently disclosed subject matter.

After PRC device 300 is installed, measurement module sets (401) scan point value (i.e. threshold), disables (402) antenna powering and sets (403) switch to testing mode. It is noted that operations (401)-(403) can be provided simultaneously or in any order.

When operations (401)-(403) are completed, measurement module 304 sends (404) start pulse towards cable 16 and checks (405) if stop pulse is received.

When the stop pulse is received, measurement module 304 saves (406) scan point value and time delay results. As detailed above with reference to FIGS. 2-3, the time delay results are further usable for time correction. Changes in scan point value can be indicative of antenna/cable state.

If the absolute value of amplitude of the reflected signal is less than the threshold corresponding to scan point and no stop pulse is received, measurement module 304 incrementally (e.g. with 0.1V interval) changes threshold value and moves (407) scan point accordingly. Measurement module 304 repeats operations 404-407 until receiving stop pulse or otherwise finishing (408) the scan (e.g. due to timeout).

It is to be understood that the invention is not limited in its application to the details set forth in the description contained herein or illustrated in the drawings. The invention is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the presently disclosed subject matter.

It will also be understood that the system according to the invention may be, at least partly, implemented on a suitably programmed computer. Likewise, the invention contemplates a computer program being readable by a computer for executing the method of the invention. The invention further contemplates a non-transitory computer-readable memory tangibly embodying a program of instructions executable by the computer for executing the method of the invention.

Those skilled in the art will readily appreciate that various modifications and changes can be applied to the embodiments of the invention as hereinbefore described without departing from its scope, defined in and by the appended claims.

1. A method of time calibration of a clock device receiving precision time information from an antenna via a cable, the clock device being operatively connected to the antenna and powering thereof, the method comprising:
a) by the clock device, disabling antenna's powering during operational process of the clock device, thus giving rise to an unpowered antenna;
b) generating by a measurement module a pulse and forwarding it toward the unpowered antenna, wherein the measurement module is implemented within the clock device;
c) measuring, by the measurement module, the roundtrip delay between the generated pulse and a measured signal reflected by the unpowered antenna, thereby obtaining a cable delay; and
d) providing time calibration in the clock device in accordance with the cable delay.

2. The method of claim 1, further comprising switching withing the clock device between an operation mode and a calibration mode comprising operations a)-d),
wherein switching from the operation mode to the calibration mode is provided prior to generating the pulse towards the unpowered antenna and enables signals incoming from the antenna to be routed to the measurement module, and
wherein switching back to the operation mode comprises enabling antenna powering.

3. The method of claim 2, further comprising continuously repeating the switching between the operation and calibration modes, thereby enabling embedded compensation for varying cable delay.

4. The method of claim 1, wherein the clock device is a primary reference clock device.

5. The method of claim 1, wherein measuring the roundtrip delay between the generated pulse and the measured signal reflected by the unpowered antenna comprises setting a threshold value defining when a reflected signal is recognized as the measured signal reflected by antenna, and wherein a reflected signal is recognized as the measured signal when the absolute value of an amplitude thereof exceeds the threshold value.

6. The method of claim 5, further comprising changing, by the measurement module, the threshold value and sampling reflected signals at a sampling point corresponding to the changed threshold value.

7. The method of claim 6, further comprising providing multiple sampling at each of several sampling points and determining the optimal sampling point enabling the minimal deviation of sampling results repeated at a specific point, wherein the measured signal reflected by antenna is sampled at the optimal sampling point.

8. The method of claim 1, further comprising:
prior to connecting the cable to the antenna, generating by the measurement module a pulse toward the cable;
measuring, by the measurement module, the roundtrip delay between the generated pulse and an open-end reflected signal, thereby obtaining an open-end cable delay; and
using the open-end cable delay as a baseline when obtaining the cable delay and/or for calculating a length of the cable.

9. A clock device operatively connected to an antenna and configured to power thereof, the clock device further configured to receive precision time information from the antenna via a cable and comprising a measurement module operatively connected to a processing and memory circuitry (PMC), wherein:
the PMC is configured to enable un-powering the antenna thus giving rise to an unpowered antenna;
the measurement module is configured to:
generate a pulse and forward it toward the unpowered antenna; and
measure the roundtrip delay between the generated pulse and a measured signal reflected by the unpowered antenna, thereby obtaining a cable delay; and
the PMC is further configured to calculate time correction in accordance with the cable delay and to enable respective time calibration in the clock device.

10. The clock device of claim 9, further comprising a GNSS (Global Navigation Satellite System) receiver operatively connected to the PMC and a switch operatively connected to the GNSS receiver, to the PMC and to the measurement module,
wherein the PMC is further configured to set the switch so to enable switching between an operation mode when signals incoming from the antenna are routed to the GNSS receiver and a calibration mode that comprises un-powering the antenna and measuring the cable delay.

11. The clock device of claim 10, wherein the PMC is configured to enable antenna powering wherein switching back to the operation mode.

12. The clock device of claim 10, wherein the PMC is further configured to set the calculated time correction to GNSS receiver.

13. The clock device of claim 10, wherein the PMC is further configured to enable continuously repeating the switching between the operation and calibration modes, thereby enabling embedded compensation for varying cable delay.

14. The clock device of claim 9 configured to operate as primary reference clock device.

15. The clock device of claim 10 further comprising a GNSS, Global Navigation Satellite System, receiver operatively connected to a grandmaster clock device.

16. The clock device of claim 9 comprising a GNSS receiver operatively connected to the antenna and receiving precision time therefrom via the cable, wherein the measurement module is comprised in the GNSS receiver.

17. The clock device of claim 9 comprising a grandmaster clock device operatively connected to an antenna and receiving precision time therefrom via the cable, wherein the measurement module is comprised in the grandmaster clock device.
